(19) United States
(12) Patent Application Publication
(10) Pub. No.: US 2015/0303877 A1
(43) Pub. Date: Oct. 22, 2015

(54) SEMICONDUCTOR DEVICE

(71) Applicant: PS4 Luxco S.a.r.l., Luxembourg (LU)

(72) Inventors: Katsuhiro KITAGAWA, Tokyo (JP); Hiroki TAKAHASHI, Tokyo (JP); Kohei NAKAMURA, Tokyo (JP)

(73) Assignee: PS4 Luxco S.a.r.l., Luxembourg (LU)

(21) Appl. No.: 14/423,570

(22) PCT Filed: Aug. 26, 2013
(86) PCT No.: PCT/JP2013/005030

§ 371 Date: Feb. 24, 2015

(30) Foreign Application Priority Data
Aug. 27, 2012 (JP) 2012-186207

(51) Int. Cl. H03F 1/02; H03F 3/45

(52) U.S. Cl. CPC H03F 1/0205; H03F 3/45076; H03F 2203/45182

(57) ABSTRACT

A semiconductor device comprises a first input terminal; a second input terminal; an inverting amplifier circuit that comprises an input node connected to a first input terminal, an inverting input node connected to a second input terminal, and an output node connected to an output terminal, amplifies a difference between a first input signal supplied to the input node and a second input signal supplied to the second input terminal, and that outputs an output signal whose polarity is inverted from that of the first input signal to the output node; and a non-inverting amplifier circuit that comprises an input node connected to a second input terminal, an inverting input node connected to a first input terminal, and an output node connected to an output terminal, amplifies a difference between the first input signal and the second input signal, and that outputs an output signal whose polarity is the same as that of the first input signal to the output node.

### TECHNICAL FIELD

### Reference to Related Application

This application is based upon and claims the benefit of priority of Japanese Patent Application No. 2012-186207, filed on Aug. 27, 2012, the disclosure of which is incorporated herein in its entirety by reference thereto.

The present invention relates to a semiconductor device, and particularly to a semi-conductor device that amplifies and outputs an input voltage of a received signal.

### BACKGROUND

A current mirror amplifier circuit detects the relative amount of an input voltage (input signal) to a reference voltage Vref, amplifies the difference between the input voltage and the reference voltage, and outputs it as an output voltage. A current minor amplifier circuit makes it possible to obtain a large-amplitude output voltage from a combination of a small-amplitude input voltage and a reference voltage Vref.

FIG. 10 is a circuit diagram illustrating the circuit configuration of a current mirror amplifier circuit as an example. With reference to FIG. 10, the current mirror amplifier circuit comprises p-channel transistors P 11 and P 12 having a source terminal connected to a power supply line that provides a power supply voltage VDD, and n-channel transistors N11 and N12 having a source terminal connected to a power supply line that provides a ground voltage VSS. Drain terminals of the p-channel transistors P11 and P12 are connected to drain terminals of the n-channel transistors N11 and N12, respectively. An input voltage Vin is supplied to a gate electrode of the p-channel transistor P11, and a reference voltage Vref is supplied to a gate electrode of the p-channel transistor P12. The drain terminal of the p-channel transistor P11, to which the input voltage Vin is supplied, is the node outputting an output voltage Vout. Two gate electrodes of the n-channel transistors N11 and N12 are connected to each other, and are further connected to the drain terminal of the p-channel transistor P 12, to which the reference voltage Vref is supplied. The current mirror amplifier circuit as described above amplifies the difference between the input voltage Vin and the reference voltage Vref and outputs it as the output voltage Vout.

FIG. 11 is a timing diagram showing a waveform of the output voltage Vout when the current mirror amplifier circuit shown in FIG. 10 receives a pulsed input voltage as the input voltage Vin and performs an ideal operation. The upper part of FIG. 11 shows the input voltage Vin and the reference voltage Vref, and the lower part of FIG. 11 shows the output voltage Vout and a logic threshold.

With reference to FIG. 11, for swing input in which the input voltage Vin goes back and forth between a low level (L) and a high level (H) in turn, the output voltage Vout behaves in such a way that it rises to its highest level and then falls to its lowest level. At this time, a period T11 from when the falling edge of the input voltage Vin crosses the reference voltage Vref to when the output voltage crosses the logic threshold is equal to a period T12 from when the rising edge of the input voltage Vin crosses the reference voltage Vref to when the output voltage Vout crosses the logic threshold. Hereinafter, such an ideal behavior of the output voltage Vout is referred to as rail-to-rail operation (R2R operation).

As related technology, Patent Literature 1 (Japanese Patent Kokai Publication No. JP-P2012-043510A, corresponding US Publication Number and published date: US2012/0044776A1; Feb. 23, 2012) describes a semiconductor memory device comprising a current minor amplifier circuit in a data input circuit. Further, Patent Literature 2 (Japanese Patent Kokai Publication No. JP-P2010-192031A, corresponding US Publication Number and published date: US2010/0208534A1; Aug. 19, 2010) describes a common semiconductor memory device.

### CITATION LIST

### Patent Literature

PTL 1: JP-P2012-043510A

PTL 2: JP-P2010-192031A

### SUMMARY

### Technical Problem

The disclosure of each Patent Literature listed above is incorporated herein in its entirety by reference thereto. The following analysis is given by the present inventors.

In the current mirror amplifier circuit shown in FIG. 10, depending on the behavior of the input voltage Vin, the amplitude of the output voltage Vout, and the amount of the capacitive component of the output part of the amplifier circuit, there may be cases where the amplification operation by the amplifier circuit is not on time. FIG. 12 is a timing diagram showing such a case as an example. The frequency of the input voltage Vin in FIG. 12 is the same as that of the input voltage Vin in FIG. 10. However, in FIG. 12, the rising and falling edges of the output voltage Vout are more gradual, compared to the case in FIG. 10.

With reference to FIG. 12, as the first part illustrates, when the frequency of the input voltage Vin is low and the input voltage Vin is maintained at a high level (or low level) for a long period of time, the output voltage Vout shows an R2R operation. However, as the second part illustrates, when the frequency of the input voltage Vin is increased, the amplification operation is too late and a rail-to-rail operation (R2R operation) is not obtained for the output voltage Vout. Further, the period T11 from when the falling edge of the input voltage Vin crosses the reference voltage Vref to when the output voltage crosses the logic threshold is longer than the period T12 from when the rising edge of the input voltage Vin crosses the reference voltage Vref to when the output voltage Vout crosses the logic threshold. In other words, areas A and B in FIG. 12 have different logic threshold arrival times. This is caused by the fact that, when the frequency of the input swing is increased, before the amplification of an output is completed, the output of a next signal is started.

For instance, in a semiconductor memory device such as a DRAM (Dynamic Random Access Memory), the logic threshold arrival time must be consistent because signals must be sent according to the data latch timing of a circuit at a later stage of an amplifier circuit provided in an amplifier unit for internal signals or of an input circuit (Patent Literature 1) for data and command signals. In other words, the amplifier circuit is required to perform a R2R operation. In order to have an amplifier circuit achieve a R2R operation, for instance, measures such as strengthening the amplifier circuit, or reducing the burden on the amplifier circuit during operation by miniaturizing the output destination of the amplifier circuit are required.

### Solution to Problem

In one aspect, there is provided a semiconductor device, comprising: a first input terminal; a second input terminal; an inverting amplifier circuit, and an non-inverting amplifier circuit. The inverting amplifier circuit comprises an input node connected to a first input terminal, an inverting input node connected to a second input terminal, and an output node connected to an output terminal, amplifies a difference between a first input signal supplied to the input node and a second input signal supplied to the second input terminal, and outputs an output signal whose polarity is inverted from that of the first input signal to the output node. The non-inverting amplifier circuit comprises an input node connected to the second input terminal, an inverting input node connected to the first input terminal, and an output node connected to an output terminal, amplifies the difference between the first input signal and the second input signal, and outputs an output signal whose polarity is the same as that of the first input signal to the output node.

In anther aspect, there is provided a semiconductor device, comprising: an input terminal to which an input signal is supplied; a reference voltage supply terminal to which a reference voltage is supplied; an output terminal; a first power supply line; a second power supply line; a first amplifier circuit connected between the first and second power supply lines, and a second amplifier circuit connected between the first and second power supply lines. The first amplifier circuit comprises: a first transistor that is connected between the first power supply line and a first node and comprises a control terminal connected to the reference voltage supply terminal; a second transistor that is connected between the first power supply line and the output terminal and comprises a control terminal connected to the input terminal; a third transistor that is connected between the first node and the second power supply line and comprises a control terminal connected to the first node; and a fourth transistor that is connected between the output terminal and the second power supply line and comprises a control terminal connected to the first node. The second amplifier circuit comprises: a fifth transistor that is connected between the first power supply line and a second node and comprises a control terminal connected to the input terminal; a sixth transistor that is provided between the first power supply line and the output terminal and comprises a control terminal connected to the reference voltage supply terminal; a seventh transistor that is provided between the second node and the second power supply line and comprises a control terminal connected to the second node; and an eighth transistor that is provided between the output terminal and the second power supply line and comprises a control terminal connected to the second node. The above features and advantages of the present invention will be more apparent from the following description of certain preferred embodiments taken in conjunction with the accompanying drawings.

### BRIEF DESCRIPTION OF DRAWINGS

FIG. 1A is a circuit diagram illustrating the circuit configuration of a semi-conductor device relating to a first exemplary embodiment as an example;

FIG. 1B is a circuit diagrams illustrating the circuit configuration of a semi-conductor device relating to a first exemplary embodiment as an example;

FIG. 2 shows timing diagrams for explaining the operation of the semiconductor device relating to the first exemplary embodiment;

FIG. 3 is a timing diagram showing the operation of the semiconductor device relating to the first exemplary embodiment as an example;

FIG. 4 is a circuit diagram illustrating the circuit configuration of a semi-conductor device relating to a second exemplary embodiment as an example;

FIG. 5 is a circuit diagram illustrating the circuit configuration of a semi-conductor device relating to a first modification of the second exemplary embodiment as an example;

FIG. 6 is a circuit diagram illustrating the circuit configuration of a semi-conductor device relating to a second modification of the second exemplary embodiment as an example;

FIG. 7 is a circuit diagram illustrating the circuit configuration of a semi-conductor device relating to a third modification of the second exemplary embodiment as an example;

FIG. 8 is a circuit diagram illustrating the circuit configuration of a semi-conductor device relating to a fourth modification of the second exemplary embodiment as an example;

FIG. 9 is a drawing showing a circuit diagram that represents constant current sources in FIGS. 6 to 8 at the transistor level as an example;

FIG. 10 is a circuit diagram illustrating the circuit configuration of a semi-conductor device of a related technology as an example;

FIG. 11 is a timing diagram showing an ideal operation of the semiconductor device of the related technology; and

FIG. 12 is a drawing for explaining a problem in the semiconductor device of the related technology.

### DESCRIPTION OF EMBODIMENTS

The invention will be now described herein with reference to illustrative exemplary embodiments. Those skilled in the art will recognize that many alternative embodiments can be accomplished using the teachings of the present invention and that the invention is not limited to the embodiments illustrated for explanatory purposes.

First, a summary of an exemplary embodiment will be given. Note that drawing reference signs used in the summary are given solely to facilitate understanding, and are not intended to limit the present invention to exemplary embodiments shown in the drawings.

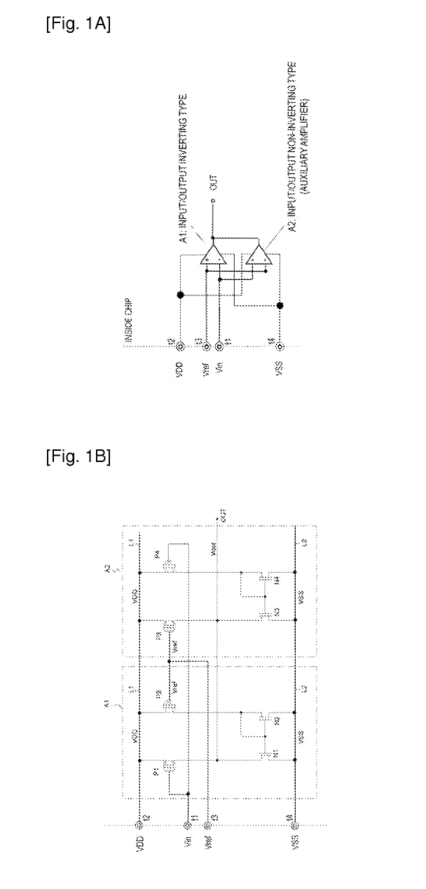

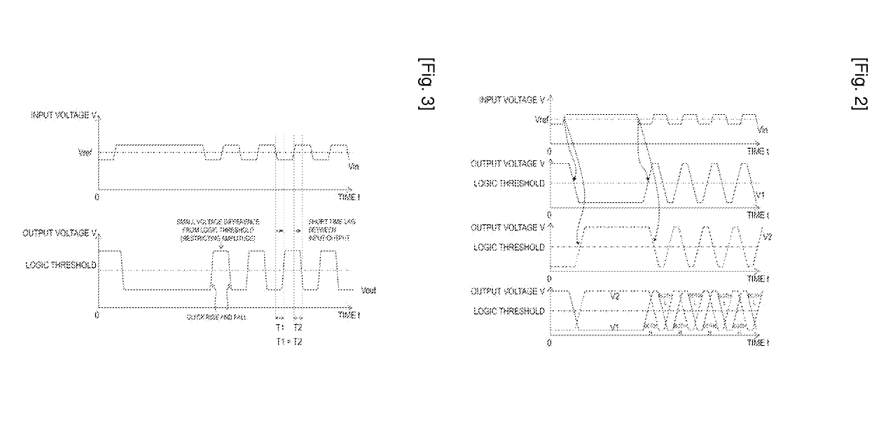

FIGS. 1A and 1B are circuit diagrams illustrating the circuit configuration of a semi-conductor device as an example. With reference to FIG. 1A, the semiconductor device comprises an inverting amplifier circuit (A1) and a non-inverting amplifier circuit (A2). The inverting amplifier circuit (A1) amplifies the difference between an input voltage (Vin) and a reference voltage (Vref), inverts the polarity, and output the result to an output terminal (OUT). The non-inverting amplifier circuit (A2) amplifies the difference between the input voltage (Vin) and the reference voltage (Vref) and outputs it to the output terminal (OUT) (without inverting the polarity). Here, the gain of the inverting amplifier circuit (A1) is larger than the gain of the non-inverting amplifier circuit (A2). Further, the delay time (the time it takes for an output potential to be inverted via a logic threshold in response to the inversion of an input potential via Vref) in the non-inverting amplifier circuit (A2) is longer than the delay time in the inverting amplifier circuit (Al).

A circuit diagram in which both the inverting amplifier circuit (A1) and the non-inverting amplifier circuit (A2) are configured using a current mirror amplifier circuit is described with reference to FIG. 1B. The inverting amplifier circuit (A1) may comprise a first transistor of a first conductivity type (p-channel transistor P1) having a gate terminal receive the input voltage (Vin) supplied to an input terminal t1, a source terminal connected to a first power supply line (L1) that provides a first power supply voltage (power supply voltage VDD) supplied to an input terminal t2, and a drain terminal connected to the output terminal (OUT); a second transistor of the first conductivity type (p-channel transistor P2) having a gate terminal receive the reference voltage (Vref) supplied to an input terminal t3 and a source terminal connected to the first power supply line (L1); a first transistor of a second conductivity type (n-channel transistor N1) having a drain terminal connected to the output terminal (OUT) and a source terminal connected to a second power supply line (L2) that provides a second power supply voltage (ground voltage VSS) supplied to an input terminal t4; and a second transistor of the second conductivity type (n-channel transistor N2) having a gate terminal connected to a gate terminal of the first transistor of the second conductivity type (N1), a drain terminal connected to a drain terminal of the second transistor of the first conductivity type (P2) and to a gate terminal of the first transistor of the second conductivity type (N1), and a source terminal connected to the second power supply line (L2). Further, the input terminals t1 to t4 includes input terminals for signals from the outside of the semiconductor device, i.e., the outside of the semi-conductor chip.

Further, the non-inverting amplifier circuit (A2) may comprise a third transistor of the first conductivity type (p-channel transistor P3) having a gate terminal receive the reference voltage (Vref), a source terminal connected to the first power supply line (L1), and a drain terminal connected to the output terminal (OUT); a fourth transistor of the first conductivity type (p-channel transistor P4) having a gate terminal receive the input voltage (Vin) and a source terminal connected to the first power supply line (L1); a third transistor of the second conductivity type (n-channel transistor N3) having a drain terminal connected to the output terminal (OUT) and a source terminal connected to the second power supply line (L2); and a fourth transistor of the second conductivity type (n-channel transistor N4) having a gate terminal connected to a gate terminal of the third transistor of the second conductivity type (N3), a drain terminal connected to a drain terminal of the fourth transistor of the first conductivity type (P4) and to a gate terminal of the third transistor of the second conductivity type (N3), and a source terminal connected to the second power supply line (L2).

Here, it is preferred that the channel width of the first transistor of the first conductivity type (P1) be wider than the channel width of the third transistor of the first conductivity type (P3). Further, it is preferred that the channel width of the first transistor of the second conductivity type (N1) be wider than the channel width of the third transistor of the second conductivity type (N3).

The semiconductor device described above is able to have the amplifier circuit achieve a rail-to-rail operation with high speed amplitude while minimizing a decrease in output level. When a pulsed input voltage is amplified and outputted as an output voltage, it is possible to equalize a period from when the rising edge of the input voltage crosses the reference voltage (Vref) to when the output voltage crosses the logic threshold and a period from when the falling edge of the input voltage crosses the reference voltage (Vref) to when the output voltage crosses the logic threshold

### First Exemplary Embodiment

A semiconductor device relating to a first exemplary embodiment will be described with reference to the drawings. FIGS. 1A and 1B are circuit diagrams illustrating the circuit configuration of the semiconductor device relating to the present exemplary embodiment as an example. With reference to FIGS. 1A and 1B, the semiconductor device comprises the inverting amplifier circuit A1 and the non-inverting amplifier circuit A2. As shown in FIG. 1, both the inverting amplifier circuit A1 and the non-inverting amplifier circuit A2 may be current mirror amplifier circuits. Note that the inverting amplifier circuit A1 and the non-inverting amplifier circuit A2 are not limited to current mirror type and nor are they limited to the circuit configuration in FIG. 1B in the present invention.

The inverting amplifier circuit A1 amplifies the difference between the input voltage Vin supplied to the input terminal t1 and the reference voltage Vref supplied to the input terminal t3, inverts the polarity, and outputs the result to the output terminal OUT. With reference to FIG. 1B, the inverting amplifier circuit A1 comprises the p-channel transistors P1 and P2, and n-channel transistors N1 and N2. The p-channel transistor P1 has the gate terminal receive the input voltage Vin, the source terminal connected to the power supply line L1 that provides the power supply voltage VDD supplied to the input terminal t2, and the drain terminal connected to the output terminal OUT. The p-channel transistor P2 has the gate terminal receive the reference voltage Vref and the source terminal connected to the power supply line L1. The n-channel transistor N1 has the drain terminal connected to the output terminal OUT and the source terminal connected to the power supply line L2 that provides the ground voltage VSS supplied to the input terminal t4. The n-channel transistor N2 has the gate terminal connected to the gate terminal of the n-channel transistor N1, the drain terminal connected to the drain terminal of the p-channel transistor P2 and to the gate terminal of the n-channel transistor N1, and the source terminal connected to the power supply line L2.

The non-inverting amplifier circuit A2 amplifies the difference between the input voltage Vin and the reference voltage Vref and outputs it to the output terminal OUT without inverting the polarity. With reference to FIG. 1B, the non-inverting amplifier circuit A2 comprises the p-channel transistors P3 and P4, and n-channel transistors N3 and N4. The p-channel transistor P3 has the gate terminal receive the reference voltage Vref, the source terminal connected to the power supply line L1, and the drain terminal connected to the output terminal OUT. The p-channel transistor P4 has the gate terminal receive the input voltage Vin and the source terminal connected to the power supply line L1. The n-channel transistor N3 has the drain terminal connected to the output terminal OUT and the source terminal connected to the power supply line L2. The n-channel transistor N4 has the gate terminal connected to the gate terminal of the n-channel transistor N3, the drain terminal connected to the drain terminal of the p-channel transistor P4 and to the gate terminal of the n-channel transistor N3, and the source terminal connected to the power supply line L2.

Here, the gain of the inverting amplifier circuit A1 is set larger than the gain of the non-inverting amplifier circuit A2, and the delay time (the time it takes for an output potential to be inverted via a logic threshold in response to the inversion of an input potential via Vref) in the non-inverting amplifier circuit A2 is set longer than the delay time in the inverting amplifier circuit A1. For instance, the channel width of the p-channel transistor P1 may be set wider than the channel width of the p-channel transistor P3, and the channel width of the n-channel transistor N1 may be set wider than the channel width of the n-channel transistor N3.

In the preset exemplary embodiment, the ratio between the channel width of the p-channel transistor P1 and the channel width of the p-channel transistor P3 is set to 2:1, as an example. Further, the ratio between the channel width of the n-channel transistor N1 and the channel width of the n-channel transistor N3 is set to 2:1. Further, the ratio between the gains of the inverting amplifier circuit A1 and the non-inverting amplifier circuit A2 is set to 2:1. Note that the ratios of the channel widths and the gains are not limited to these values.

Next, the operation of the semiconductor device of the present exemplary embodiment will described with reference to the drawings. FIG. 2 shows timing diagrams for explaining the operation of the semiconductor device relating to the present exemplary embodiment. The upper part of FIG. 2 shows a timing diagram showing the waveforms of the input voltage Vin and the reference voltage Vref. The middle part of FIG. 2 shows timing diagrams showing the waveform of an output voltage V1 of the inverting amplifier circuit Al and the waveform of an output voltage V2 of the non-inverting amplifier circuit A2. The lower part of FIG. 2 shows a timing diagram showing the output voltages V1 and V2 superimposed.

With reference to FIG. 2, the inverting amplifier circuit A1 amplifies the difference between the input voltage Vin and the reference voltage Vref, inverts the polarity, and outputs the result. Meanwhile, the non-inverting amplifier circuit A2 amplifies and outputs the difference between the input voltage Vin and the reference voltage Vref. The output timing of the inverting amplifier circuit A1 has a delay corresponding to a gate of the p-channel transistor P1 because a voltage outputted to the output terminal changes due to a change in the input of the p-channel transistor P1. Further, output timing of the non-inverting amplifier circuit A2 has two gates' worth of delay since, after the input of the p-channel transistor P4 changes, the gate voltage of the n-channel transistor changes and so does the voltage outputted to the output terminal OUT. Therefore, the output timing of the inverting amplifier circuit A1 is faster than the output timing of the non-inverting amplifier circuit A2. In other words, the delay time in the non-inverting amplifier circuit A2 is longer than the delay time in the inverting amplifier circuit A1.

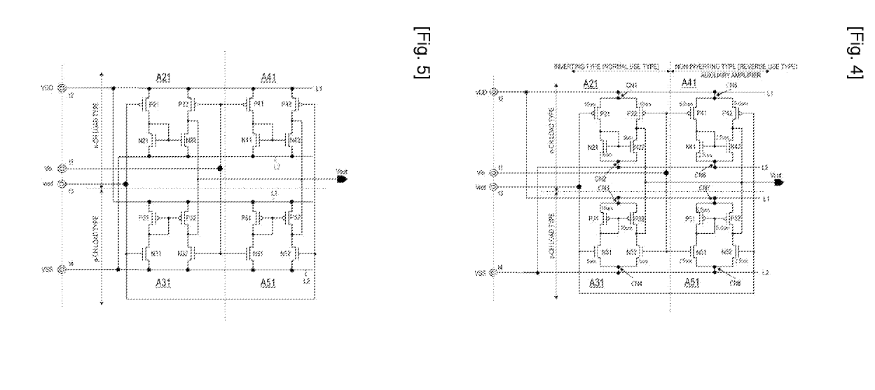

FIG. 3 is a timing diagram showing the operation of the semiconductor device relating to the present exemplary embodiment as an example. The upper part of FIG. 3 shows a timing diagram showing the waveforms of the input voltage Vin and the reference voltage Vref. The lower part of FIG. 3 shows a timing diagram showing the waveform of an output voltage Vout, a composite of the output voltage V1 of the inverting amplifier circuit A1 and the output voltage V2 of the non-inverting amplifier circuit A2.

With reference to FIGS. 2 and 3, the waveform of the output voltage Vout will be described. Further, in the lower part of FIG. 2, periods during which both the output voltages V1 and V2 are higher than the logic threshold are called Both H Period, periods during which both the output voltages V1 and V2 are lower than the logic threshold are called Both L Period, and other periods during which one of the output voltages V1 and V2 is higher than the logic threshold and the other is lower than the logic threshold are called Bus Fight Period.

In Bus Fight Periods shown in the lower part of FIG. 2, the value of the output voltage Vout obtained by combining the output voltages V1 and V2 becomes the intermediate value of the output voltages V1 and V2. When the drive capabilities of the two current mirror amplifier circuits A2 and A2 are equal, the level of the output voltage becomes the intermediate value of the original swing width as a result of the bus fight. In the preset exemplary embodiment, since the ratio between the gains of the inverting amplifier circuit A1 and the non-inverting amplifier circuit A2 is set to 2:1, the output voltage Vout corresponding to the polarity of the inverting amplifier circuit Al is obtained as shown in FIG. 3. Further, the level of the output voltage Vout depends on the sizes of the inverting amplifier circuit Al and the non-inverting amplifier circuit A2, and the swing width (amplitude) of the output voltage Vout is a half of the swing width of the output voltage V1 of the inverting amplifier circuit A1 in the present exemplary embodiment. In other words, a full swing operation is not reached due to the fact that the output voltage V1 of the inverting amplifier circuit Al is partially offset by the output voltage V2 of the non-inverting amplifier circuit A2 and the amplitude is restricted.

Further, the output timing of the non-inverting amplifier circuit A2 is slightly delayed, compared to the output timing of the inverting amplifier circuit A1. At this time, as shown in the lower part of FIG. 2, immediately after the level of the output voltage V1 becomes higher (or lower) than the logic threshold, a Both H Period (or Both L Period) occurs without a bus fight and the polarities of the output voltages of the inverting amplifier circuit A1 and the non-inverting amplifier circuit A2 match. During the Both H Period (or Both L Period), the non-inverting amplifier circuit A2 assists the operation of the inverting amplifier circuit A1 and expands the size of the amplifier circuit. Therefore, the rising edge (or falling edge) of the output voltage Vout becomes steep.

Meanwhile, in Bus Fight Period during which the polarities of the output voltage V2 of the non-inverting amplifier circuit A2 and the output voltage V1 of the inverting amplifier circuit Al are reversed, since they cancel each other out, the potential difference between the output voltage Vout and the logic threshold becomes small (i.e., the amplitude of the output voltage Vout is restricted).

According to the semiconductor device relating to the present exemplary embodiment, the following effects can be obtained. By combining the output voltage V1 of the inverting amplifier circuit Al and the output voltage V2 of the non-inverting amplifier circuit A2, a rail-to-rail operation with high speed amplitude can be achieved while minimizing a decrease in the output level in amplification. When the pulsed input voltage Vin is amplified and outputted as the output voltage Vout, it is possible to equalize a period from when the rising edge of the input voltage Vin crosses the reference voltage Vref to when the output voltage Vout crosses the logic threshold and a period from when the falling edge of the input voltage Vin crosses the reference voltage Vref to when the output voltage Vout crosses the logic threshold.

According to the semiconductor device described above, the rising and falling edges of the output voltage Vout become steep, and this is advantageous in high-speed signal transmission. Further, due to the restriction on the amplitude of the output voltage Vout, the potential difference between the output circuit Vout and logic threshold in a rail-to-rail operation becomes small and the time it takes for the output voltage Vout to rise or fall is further reduced. Further, by employing the same current minor configuration for the circuit configuration of the inverting amplifier circuit A1 and non-inverting amplifier circuit A2, the amplitude of the output voltage Vout can be easily adjusted based on geometric parameters such as the size ratio between the amplifier circuits.

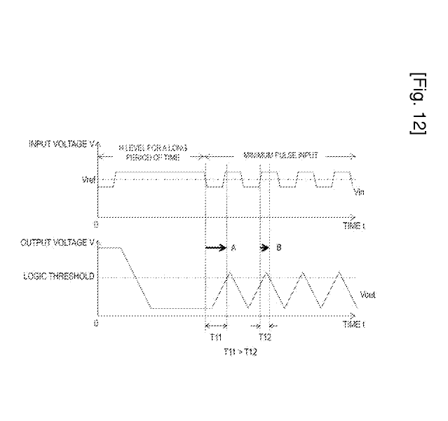

Further, according to the semiconductor device of the present exemplary embodiment, because the output voltage V1 of the inverting amplifier circuit A1 and the output voltage V2 of the non-inverting amplifier circuit A2 offset each other, the amplitude of the output voltage Vout is smaller than in the case where only the inverting amplifier circuit A1 is provided (FIG. 11). However, in the present exemplary embodiment, since a sufficiently large value can still be obtained as the potential difference between the output voltage Vout and the logic threshold, the operation of subsequent circuits is not affected.

### Second Exemplary Embodiment

Next, a semiconductor device relating to a second exemplary embodiment will be described with reference to the drawings. In the first exemplary embodiment, the explanation was made using the current mirror amplifier circuits that uses n-channel transistors as loads, however, in order to complement each other's characteristics, a current mirror amplifier circuit using an n-channel transistor as a load and a current mirror amplifier circuit using a p-channel transistor as a load are often used as a pair.

In the present exemplary embodiment, as shown in FIG. 4, each of an inverting amplifier circuit and a non-inverting amplifier circuit is constituted by a pair of an n-channel transistor load type current mirror amplifier circuit and a p-channel transistor load type current mirror amplifier circuit.

An n-channel transistor load type current minor amplifier circuit A21 constituting the inverting amplifier circuit comprises a p-channel transistor P21 connected between a common node CN1 connected to an input terminal t2 to which the power supply VDD is supplied and an input node of a current mirror and having a gate connected to an input terminal t3 to which the reference voltage Vref is supplied; an n-channel transistor N21 connected between the input node of the current mirror and a common node CN2 connected to an input terminal t4 to which the power supply VSS is supplied and having a gate connected to the input node of the current mirror; a p-channel transistor P22 connected between the common node CN1 and an output terminal OUT and having a gate connected to an input terminal t1 to which the input voltage Vin is supplied; and a n-channel transistor N22 connected between the output terminal OUT and the common node CN2 and having a gate connected to the input node of the current mirror.

A p-channel transistor load type current minor amplifier circuit A31 constituting the inverting amplifier circuit comprises an p-channel transistor P31 connected between a common node CN3 connected to the input terminal t2 (the power supply VDD) and an input node of a current minor and having a gate connected to the input node of the current mirror; an n-channel transistor N31 connected between the input node of the current mirror and a common node CN4 and having a gate connected to the input terminal t3 (the reference voltage Vref); a p-channel transistor P32 provided between the common node CN3 and the output terminal OUT and having a gate connected to the input node of the current mirror; and a n-channel transistor N32 provided between the output terminal OUT and the common node CN4 and having a gate connected to the input terminal t1 (the input voltage Vin).

An n-channel transistor load type current minor amplifier circuit A41 constituting the non-inverting amplifier circuit comprises a p-channel transistor P41 connected between a common node CN5 connected to the input terminal t2 (the power supply VDD) and an input node of a current mirror and having a gate connected to the input voltage supply terminal Vin; an n-channel transistor N41 connected between the input node of the current mirror and a common node CN6 connected to the input terminal t4 (the power supply VSS) and having a gate connected to the input node of the current mirror; a p-channel transistor P42 connected between the common node CN5 and the output terminal OUT and having a gate connected to the input terminal t3 (the reference voltage Vref); and a n-channel transistor N42 connected between the output terminal OUT and the common node CN6 and having a gate connected to the input node of the current mirror.

A p-channel transistor load type current minor amplifier circuit A51 constituting the non-inverting amplifier circuit comprises an p-channel transistor P51 connected between a common node CN7 connected to the input terminal t2 (the power supply VDD) and an input node of a current mirror and having a gate connected to the input node of the current mirror; an n-channel transistor N51 connected between the input node of the current mirror and a common node CN8 and having a gate connected to the input terminal t1 (the input voltage Vin); a p-channel transistor P52 provided between the common node CN7 and the output terminal OUT and having a gate connected to the input node of the current mirror; and a n-channel transistor N52 provided between the output terminal OUT and the common node CN8 and having a gate connected to the input terminal t3 (the reference voltage Vref).

Further, as an example, each of the p-channel transistors P21, P22, P31, and P32 constituting the inverting amplifier circuit has a channel width w of 10 mm, and each of the n-channel transistors N21, N22, N31, and N32 has a channel width w of 5 mm. Further, each of the p-channel transistors P41, P42, P51, and P52 constituting the non-inverting amplifier circuit used supplementarily has a channel width w of 5 mm, and each of the n-channel transistors N41, N42, N51, and N52 has a channel width of 2.5 mm, having smaller channel widths than the inversion type transistors.

### First Modification

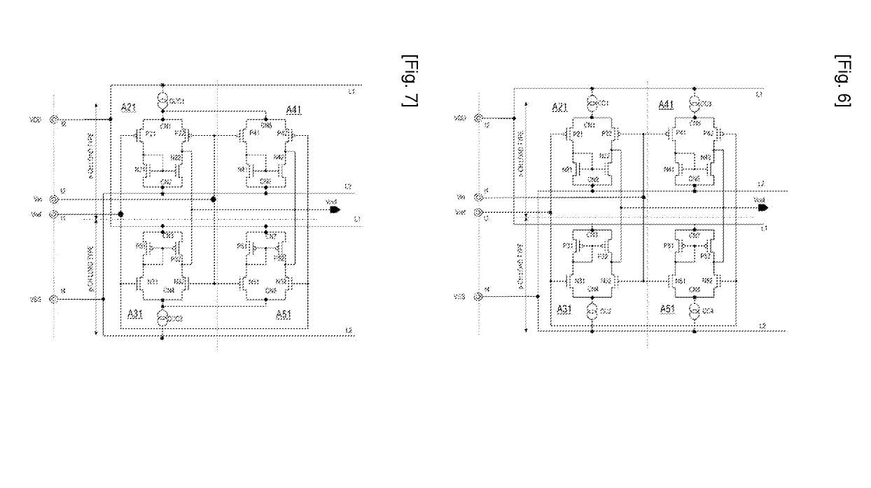

Next, a first modification of the second exemplary embodiment will be described using FIG. 5. In the second exemplary embodiment, the source sides of the transistors constituting the current minor loads are connected to the corresponding common nodes CN1 to CN8. The modification example differs from the second exemplary embodiment in that the source sides of the transistors are directly connected to the power supply line L1 (the power supply VDD) or the power supply line L2 (the power supply VSS). Since the modification example is identical to the second exemplary embodiment in other points, the explanation will be omitted.

### Second Modification

Next, a second modification of the second exemplary embodiment will be described using FIG. 6. In the second exemplary embodiment, the common nodes CN1 to CN8 are connected to the corresponding power supply line L1 (VDD) or power supply line L2 (VSS). The present modification differs from the second exemplary embodiment in that the common nodes are connected to the power supply line via constant current sources. In other words, a constant current source CC1 is provided between the common node CN1 and the power supply line L1 (VDD); a constant current source CC2 is provided between the common node CN4 and the power supply line L2 (VSS); a constant current source CC3 is provided between the common node CN5 and the power supply line L1 (VDD); and a constant current source CC4 is provided between the common node CN8 and the power supply line L2 (VSS). These constant current sources CC1 to CC4 are disposed opposite to the current mirror loads with the transistors connected to the input voltage supply terminal and the reference voltage supply terminal interposed therebetween.

### Third Modification

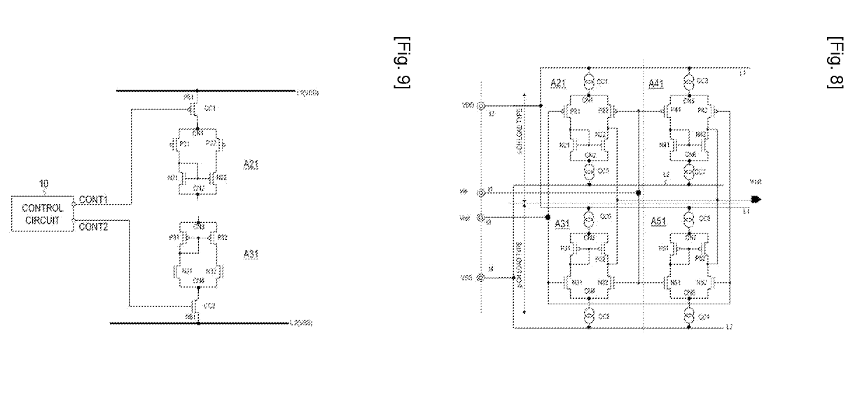

Next, a third modification of the second exemplary embodiment will be described using FIG. 7. In the second modification, the four constant current sources CC1 to CC4 are provided corresponding to the amplifier circuits A21, A31, A41, and A51. In the present modification, the amplifier circuits A21 and A41 share a constant current source CCC1, and the amplifier circuits A31 and A51 share a constant current source CCC2.

### Fourth Modification

Next, a fourth modification of the second exemplary embodiment will be described using FIG. 8. In the second modification, the four constant current sources CC1 to CC4 are provided corresponding to the amplifier circuits A21, A31, A41, and A51. In addition to these, in the present modification, constant current sources CCS, CC6, CC7, and CC8 are further provided between the common node CN2 and the power supply line L2 (VSS), between the common node CN3 and the power supply line L1 (VDD), between the common node CN6 and the power supply line L2 (VSS), and between the common node CN7 and the power supply line L1 (VDD), respectively.

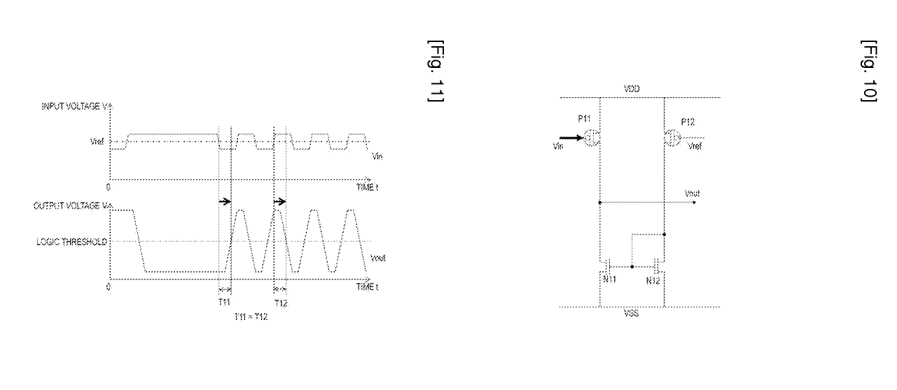

Further, FIG. 9 is a diagram representing each constant current source circuit at the transistor level. More concretely, FIG. 9 shows an example in which the constant current source CC1 added to the p-channel transistor load type amplifier circuit A21 in FIG. 6 is constituted by a p-channel transistor P61, and the constant current source CC2 added to the n-channel transistor load type amplifier circuit A31 is constituted by an n-channel transistor N61. Further, control signals CONT1 and CONT2 are supplied from a control circuit 10 to gates of the n-channel transistor N61 and the p-channel transistor P61 constituting the constant current sources in order to restrict the current value. Two constant current sources CC1 and CC2 are described in FIG. 9, however, the other constant current sources can be configured in the same manner. Further, constant current sources are usually constituted using p-channel transistors on the high potential side (the VDD side in the present example) and n-channel transistors on the low potential side (the VSS side in the present example).

In the exemplary embodiments and the modifications, the descriptions were given regarding data input, however, the present invention can be suitably applied to a data input circuit part of a data input/output circuit such as a DRAM. Further, it can also be used for an address/command input circuit if a DRAM is capable of DDR operation for address/command input such as a mobile product. It is also suitable to apply the present invention to a circuit that receives input signals on both rising and falling edges of the clock.

Further, each disclosure of Patent Literatures listed above is incorporated herein in its entirety by reference thereto. It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned. In particular, regarding the ranges of numeric values stated in the present disclosure, it should be understood that a numeric value or small range included in these ranges is used as a concrete example even when no specific explanation is provided.

The following modes are also possible within the present disclosure.

(Mode 1)

A semiconductor device may be the semiconductor device according to the above one aspect.

(Mode 2)

In the semiconductor device, each of the inverting amplifier circuit and the non-inverting amplifier circuit may comprise a current minor amplifier circuit.

(Mode 3)

In the semiconductor device, the inverting amplifier circuit may comprise: a first transistor of a first conductivity type that comprises a gate terminal receiving the input voltage, a source terminal connected to a first power supply line that supplies a first power supply voltage, and a drain terminal connected to the output terminal; a second transistor of the first conductivity type that comprises a gate terminal receiving the reference voltage and a source terminal connected to the first power supply line; a third transistor of a second conductivity type that comprises a drain terminal connected to the output terminal and a source terminal connected to a second power supply line that supplies a second power supply voltage; and a fourth transistor of the second conductivity type that comprises a gate terminal connected to a gate terminal of the third transistor, a drain terminal connected to a drain terminal of the second transistor and to a gate terminal of the third transistor, and a source terminal connected to the second power supply line.

(Mode 4)

In the semiconductor device, the non-inverting amplifier circuit may comprise: a fifth transistor of the first conductivity type that comprises a gate terminal receiving the reference voltage, a source terminal connected to the first power supply line, and a drain terminal connected to the output terminal; a sixth transistor of the first conductivity type that comprises a gate terminal receiving the input voltage and a source terminal connected to the first power supply line; a seventh transistor of the second conductivity type that comprises a drain terminal connected to the output terminal and a source terminal connected to the second power supply line; and an eighth transistor of the second conductivity type that comprises a gate terminal connected to a gate terminal of the seventh transistor, a drain terminal connected to a drain terminal of the sixth transistor and to a gate terminal of the seventh transistor, and a source terminal connected to the second power supply line.

(Mode 5)

In the semiconductor device, a channel width of the first transistor may be wider than a channel width of the fifth transistor, and a channel width of the third transistor may be wider than a channel width of the seventh transistor.

(Mode 6)

In the semiconductor device, the input terminal may be a data input terminal, and the second input terminal may be a reference voltage input terminal to which a reference voltage, used by the first amplifier circuit and the second amplifier circuit to determine a level of data supplied to the data input terminal and output an output signal based on the determination to the output node, is supplied.

(Mode 7)

A semiconductor device may be the semiconductor device according to the above other aspect.

(Mode 8)

The semiconductor device may comprise: a third amplifier circuit provided between the first and the second power supply lines, the third amplifier circuit comprising: a ninth transistor that is connected between the first power supply line and a third node and comprises a control terminal connected to the third node; a tenth transistor that is connected between the first power supply line and the output terminal and comprises a control terminal connected to the third node; an eleventh transistor that is provided between the third node and the second power supply line and comprises a control terminal connected to the reference voltage supply terminal; and a twelfth transistor that is provided between the output terminal and the second power supply line and comprises a control terminal connected to the input terminal; and a fourth amplifier circuit provided between the first and the second power supply lines, the fourth amplifier circuit comprising: a thirteenth transistor that is provided between the first power supply line and a fourth node and comprises a control terminal connected to the fourth node; a fourteenth transistor that is provided between the first power supply line and the output terminal and comprises a control terminal connected to the fourth node; a fifteenth transistor that is provided between the fourth node and the second power supply line and comprises a control terminal connected to the input terminal; and a sixteenth transistor that is provided between the output terminal and the second power supply line and comprises a control terminal connected to the reference voltage supply terminal.

(Mode 9)

In the semiconductor device, the first transistor and the second transistor may be connected to the first power supply line via a first common node, and the fifth transistor and the sixth transistor may be connected to the first power supply line via a second common node.

(Mode 10)

In the semiconductor device, the first transistor and the second transistor may be connected to each other via a first constant current source circuit connected between the first common node and the first power supply line, and the fifth transistor and the sixth transistor may be connected to each other via a second constant current source circuit connected between the second common node and the first power supply line.

(Mode 11)

In the semiconductor device, each of the first common node and the second common node may be connected to the first power supply line via a first constant current source circuit and not via any other constant current source circuit.

(Mode 12)

In the semiconductor device, transistors of a first conductivity type among the first to fourth transistors may have a wider channel width than transistors of the first conductivity type among the fifth to eighth transistors, and remaining transistors of a second conductivity type among the first to fourth transistors may have a wider channel width than remaining transistors of the second conductivity type among the fifth to eighth transistors.

(Mode 13)

In the semiconductor device, the first transistor and the second transistor may be connected to the first power supply line via a first common node, the fifth transistor and the sixth transistor may be connected to the first power supply line via a second common node, the third transistor and the fourth transistor may be connected to the second power supply line via a third common node, and the seventh transistor and the eighth transistor may be connected to the second power supply line via a fourth common node.

(Mode 14)

In the semiconductor device, the first transistor and the second transistor may be connected to each other via a first constant current source circuit connected between the first common node and the first power supply line, the fifth transistor and the sixth transistor may be connected to each other via a second constant current source circuit connected between the second common node and the first power supply line, the third transistor and the fourth transistor may be connected to each other via a third constant current source circuit connected between the third common node and the second power supply line, and the seventh transistor and the eighth transistor may be connected to each other via a fourth constant current source circuit connected between the fourth common node and the second power supply line.

(Mode 15)

In the semiconductor device, each of the first common node and the second common node may be connected to the first power supply line via a first constant current source circuit and not via any other constant current source circuit, and each of the third common node and the fourth common node may be connected to the second power supply line via a second constant current source circuit and not via any other constant current source circuit.

(Mode 16)

In the semiconductor device, the first transistor and the second transistor may be connected to the first power supply line via a first common node, the third transistor and the fourth transistor may be connected to the second power supply line via a second common node, the fifth transistor and the sixth transistor may be connected to the first power supply line via a third common node, the seventh transistor and the eighth transistor may be connected to the second power supply line via a fourth common node, the ninth transistor and the tenth transistor may be connected to the first power supply line via a fifth common node, the eleventh transistor and the twelfth transistor may be connected to the second power supply line via a sixth common node, the thirteenth transistor and the fourteenth transistor may be connected to the first power supply line via a seventh common node, and the fifteenth transistor and the sixteenth transistor may be connected to the second power supply line via an eighth common node.

(Mode 17)

The semiconductor device may comprise: a first constant current source circuit provided between the first common node and the first power supply line; a second constant current source circuit provided between the fourth common node and the second power supply line; a third constant current source circuit provided between the fifth common node and the first power supply line; and a fourth constant current source circuit provided between the eighth common node and the second power supply line.

(Mode 18)

The semiconductor device may comprise: a fifth constant current source circuit provided between the second common node and the second power supply line; a sixth constant current source circuit provided between the third common node and the first power supply line; a seventh constant current source circuit provided between the sixth common node and the second power supply line; and an eighth constant current source circuit provided between the seventh common node and the first power supply line.

### REFERENCE SIGNS LIST

10: control circuit

A1: inverting amplifier circuit

A2: non-inverting amplifier circuit

CC1 to CC4, CCC1, CCC2: constant current source

CONT1, CONT2: control signal

L1, L2: power supply line

N1 to N4, N11, N12: n-channel transistor

N21, N22, N31, N32: n-channel transistor

N41, N42, N51, N52, N61: n-channel transistor

OUT: output terminal

P1 to P4, P11, P12: p-channel transistor

P21, P22, P31, P32: p-channel transistor

P41, P42, P51, P52, P61: p-channel transistor

T1, T2, T11, T12, T21, T22: period

t1 to t4: input terminal

V1, V2: output voltage

VDD: power supply voltage

Vin: input voltage

Vout: output voltage

Vref: reference voltage

VSS: ground voltage

1. A semiconductor device, comprising:
a first input terminal;
a second input terminal;
an inverting amplifier circuit that comprises an input node connected to a first input terminal, an inverting input node connected to a second input terminal, and an output node connected to an output terminal, amplifies a difference between a first input signal supplied to the input node and a second input signal supplied to the second input terminal, and that outputs an output signal whose polarity is inverted from that of the first input signal to the output node; and
a non-inverting amplifier circuit that comprises an input node connected to the second input terminal, an inverting input node connected to the first input terminal, and an output node connected to an output terminal, amplifies the difference between the first input signal and the second input signal, and that outputs an output signal whose polarity is the same as that of the first input signal to the output node.

2. The semiconductor device according to claim 1, wherein
each of the inverting amplifier circuit and the non-inverting amplifier circuit comprises a current minor amplifier circuit.

3. The semiconductor device according to claim 2, wherein
the inverting amplifier circuit comprises:
a first transistor of a first conductivity type that comprises a gate terminal receiving the input voltage, a source terminal connected to a first power supply line that supplies a first power supply voltage, and a drain terminal connected to the output terminal;
a second transistor of the first conductivity type that comprises a gate terminal receiving the reference voltage and a source terminal connected to the first power supply line;
a third transistor of a second conductivity type that comprises a drain terminal connected to the output terminal and a source terminal connected to a second power supply line that supplies a second power supply voltage; and
a fourth transistor of the second conductivity type that comprises a gate terminal connected to a gate terminal of the third transistor, a drain terminal connected to a drain terminal of the second transistor and to a gate terminal of the third transistor, and a source terminal connected to the second power supply line.

4. The semiconductor device according to claim 3, wherein
the non-inverting amplifier circuit comprises:
a fifth transistor of the first conductivity type that comprises a gate terminal receiving the reference voltage, a source terminal connected to the first power supply line, and a drain terminal connected to the output terminal;
a sixth transistor of the first conductivity type that comprises a gate terminal receiving the input voltage and a source terminal connected to the first power supply line;
a seventh transistor of the second conductivity type that comprises a drain terminal connected to the output terminal and a source terminal connected to the second power supply line; and
an eighth transistor of the second conductivity type that comprises a gate terminal connected to a gate terminal of the seventh transistor, a drain terminal connected to a drain terminal of the sixth transistor and to a gate terminal of the seventh transistor, and a source terminal connected to the second power supply line.

5. The semiconductor device according to claim 4, wherein
a channel width of the first transistor is wider than a channel width of the fifth transistor, and
a channel width of the third transistor is wider than a channel width of the seventh transistor.

6. The semiconductor device according to claim 1, wherein
the input terminal is a data input terminal, and
the second input terminal is a reference voltage input terminal to which a reference voltage, used by the first amplifier circuit and the second amplifier circuit to determine a level of data supplied to the data input terminal and output an output signal based on the determination to the output node, is supplied.

7. A semiconductor device, comprising:
an input terminal to which an input signal is supplied;
a reference voltage supply terminal to which a reference voltage is supplied;
an output terminal;
a first power supply line;
a second power supply line;
a first amplifier circuit connected between the first and second power supply lines, the first amplifier circuit comprising:
a first transistor that is connected between the first power supply line and a first node and comprises a control terminal connected to the reference voltage supply terminal;
a second transistor that is connected between the first power supply line and the output terminal and comprises a control terminal connected to the input terminal;
a third transistor that is connected between the first node and the second power supply line and comprises a control terminal connected to the first node; and
a fourth transistor that is connected between the output terminal and the second power supply line and comprises a control terminal connected to the first node; and
a second amplifier circuit connected between the first and second power supply lines, the second amplifier circuit comprising:
a fifth transistor that is connected between the first power supply line and a second node and comprises a control terminal connected to the input terminal;
a sixth transistor that is provided between the first power supply line and the output terminal and comprises a control terminal connected to the reference voltage supply terminal;
a seventh transistor that is provided between the second node and the second power supply line and comprises a control terminal connected to the second node; and
an eighth transistor that is provided between the output terminal and the second power supply line and comprises a control terminal connected to the second node.

8. The semiconductor device according to claim 7 comprising:
a third amplifier circuit provided between the first and the second power supply lines, the third amplifier circuit comprising:
a ninth transistor that is connected between the first power supply line and a third node and comprises a control terminal connected to the third node;
a tenth transistor that is connected between the first power supply line and the output terminal and comprises a control terminal connected to the third node;
an eleventh transistor that is provided between the third node and the second power supply line and comprises a control terminal connected to the reference voltage supply terminal; and
a twelfth transistor that is provided between the output terminal and the second power supply line and comprises a control terminal connected to the input terminal; and
a fourth amplifier circuit provided between the first and the second power supply lines, the fourth amplifier circuit comprising:
a thirteenth transistor that is provided between the first power supply line and a fourth node and comprises a control terminal connected to the fourth node;
a fourteenth transistor that is provided between the first power supply line and the output terminal and comprises a control terminal connected to the fourth node;
a fifteenth transistor that is provided between the fourth node and the second power supply line and comprises a control terminal connected to the input terminal; and
a sixteenth transistor that is provided between the output terminal and the second power supply line and comprises a control terminal connected to the reference voltage supply terminal.

9. The semiconductor device according to claim 7, wherein
the first transistor and the second transistor are connected to the first power supply line via a first common node, and
the fifth transistor and the sixth transistor are connected to the first power supply line via a second common node.

10. The semiconductor device according to claim 9, wherein
the first transistor and the second transistor are connected to each other via a first constant current source circuit connected between the first common node and the first power supply line, and
the fifth transistor and the sixth transistor are connected to each other via a second constant current source circuit connected between the second common node and the first power supply line.

11. The semiconductor device according to claim 9, wherein each of the first common node and the second common node is connected to the first power supply line via a first constant current source circuit and not via any other constant current source circuit.

12. The semiconductor device according to claim 7, wherein transistors of a first conductivity type among the first to fourth transistors have a wider channel width than transistors of the first conductivity type among the fifth to eighth transistors, and
remaining transistors of a second conductivity type among the first to fourth transistors have a wider channel width than remaining transistors of the second conductivity type among the fifth to eighth transistors.

13. The semiconductor device according to claim 7, wherein
the first transistor and the second transistor are connected to the first power supply line via a first common node,
the fifth transistor and the sixth transistor are connected to the first power supply line via a second common node,
the third transistor and the fourth transistor are connected to the second power supply line via a third common node, and
the seventh transistor and the eighth transistor are connected to the second power supply line via a fourth common node.

14. The semiconductor device according to claim 13, wherein
the first transistor and the second transistor are connected to each other via a first constant current source circuit connected between the first common node and the first power supply line,
the fifth transistor and the sixth transistor are connected to each other via a second constant current source circuit connected between the second common node and the first power supply line,
the third transistor and the fourth transistor are connected to each other via a third constant current source circuit connected between the third common node and the second power supply line, and
the seventh transistor and the eighth transistor are connected to each other via a fourth constant current source circuit connected between the fourth common node and the second power supply line.

15. The semiconductor device according to claim 13, wherein
each of the first common node and the second common node is connected to the first power supply line via a first constant current source circuit and not via any other constant current source circuit, and
each of the third common node and the fourth common node is connected to the second power supply line via a second constant current source circuit and not via any other constant current source circuit.

16. The semiconductor device according to claim 8, wherein
the first transistor and the second transistor are connected to the first power supply line via a first common node,
the third transistor and the fourth transistor are connected to the second power supply line via a second common node,
the fifth transistor and the sixth transistor are connected to the first power supply line via a third common node,
the seventh transistor and the eighth transistor are connected to the second power supply line via a fourth common node,
the ninth transistor and the tenth transistor are connected to the first power supply line via a fifth common node,
the eleventh transistor and the twelfth transistor are connected to the second power supply line via a sixth common node,
the thirteenth transistor and the fourteenth transistor are connected to the first power supply line via a seventh common node, and
the fifteenth transistor and the sixteenth transistor are connected to the second power supply line via an eighth common node.

17. The semiconductor device according to claim 16 comprising:
a first constant current source circuit provided between the first common node and the first power supply line;
a second constant current source circuit provided between the fourth common node and the second power supply line;
a third constant current source circuit provided between the fifth common node and the first power supply line; and
a fourth constant current source circuit provided between the eighth common node and the second power supply line.

18. The semiconductor device according to claim 17 comprising:
a fifth constant current source circuit provided between the second common node and the second power supply line;
a sixth constant current source circuit provided between the third common node and the first power supply line;
a seventh constant current source circuit provided between the sixth common node and the second power supply line; and
an eighth constant current source circuit provided between the seventh common node and the first power supply line.
